(19) United States
(12) Patent Application Publication
(10) Pub. No.: US 2008/0210991 A1
(43) Pub. Date: Sep. 4, 2008

(54) CMOS IMAGE SENSOR AND METHOD OF MANUFACTURING

(76) Inventor: Keun-Hyuk Lim, Seoul (KR)

Correspondence Address: SHERR & NOURSE, PLLC, 620 HERNDON PARKWAY, SUITE 200, HERNDON, VA, 20170, US

(21) Appl. No.: 11/963,500

(22) Filed: Dec. 21, 2007

(30) Foreign Application Priority Data
Dec. 29, 2006 (KR) 10-2006-0137543

(51) Int. Cl. H01L 27/146; H01L 31/18

(52) U.S. Cl. 257/292; 438/59; 257/E27.133

(57) ABSTRACT

A CMOS image sensor capable of preventing leakage current of a transfer transistor and a method of manufacturing thereof are disclosed. Embodiments relate to a complementary metal-oxide-silicon (CMOS) image sensor including a transfer transistor. The transfer transistor includes an epi-layer formed over a semiconductor substrate defined by a photodiode area, an active area, and a device isolation area. A device isolation film may be formed in the device isolation area. A gate electrode may be formed over the epi-layer for the transfer transistor with a gate insulating film interposed therebetween. A first dopant diffusion area may be formed by implanting first dopant ions into the epi-layer of the photodiode area. A potential well area may be formed in the first dopant diffusion area adjacent to the gate electrode. A second dopant diffusion area may be formed by implanting second dopant ions into the epi-layer of a side-surface floating diffusion area of a gate spacer.

The present application claims priority under 35 U.S.C. 119 to Korean Patent Application No. 10-2006-0137543, filed on Dec. 29, 2006, which is hereby incorporated by reference in its entirety.

### BACKGROUND

An image sensor converts an optical image into an electrical signal. Image sensors may be classified as complementary metal-oxide-silicon (CMOS) image sensors or charge coupled device (CCD) image sensors. The CCD image sensor has better photosensitivity and lower noise compared with the CMOS image sensor. However, CCD image sensors may be more difficult to fabricate into highly integrated devices and have higher power consumption.

In contrast, CMOS image sensors have a simpler manufacturing process, higher integration, and lower power consumption, compared with CCD image sensors. Recently, as technology for manufacturing semiconductor devices has advanced, technology for manufacturing CMOS image sensors have advanced. Pixels of the CMOS image sensor may include photodiodes for receiving light and transistors for controlling image signals input through the photodiodes. CMOS image sensors may be divided into a 3T type, a 4T type, or a 5T type depending on the number of transistors. A 3T type CMOS image sensor includes a photodiode and three transistors while the 4T type CMOS image sensor includes a photodiode and four transistors.

FIG. 1 shows a plan view showing a related CMOS image sensor. Referring to FIG. 1, a 4T type CMOS image sensor includes a photodiode area PD, a transfer transistor Tx, a reset transistor Rx, and a drive transistor Dx. The photodiode area PD is formed in the widest portion of an active area 1. The transfer transistor Tx, the reset transistor Rx, and the drive transistor Dx are formed to overlap the active area 1 excluding the photodiode area PD. A selection transistor Sx may be included to bring the total number of transistors to four per photodiode.

The photodiode PD detects incident light and generates charges according to the intensity of light. The transfer transistor Tx carries the charges generated at the photodiode PD to a floating diffusion area FD. Before carrying the charges, the floating diffusion area FD moves electrons received from the photodiodes PD to the reset transistor Tx to turn on the reset transistor Rx. Accordingly, the floating diffusion area FD may be set to a predetermined low charge state having a predetermined level.

The reset transistor Rx discharges the charges stored in the floating diffusion area FD, in order to detect a signal. The drive transistor Dx functions as a source follower for converting the charges received from the photodiodes PD into a voltage signal.

As shown in FIG. 2, a CMOS image sensor may include a P-type epi-layer 4, a device isolation film 6, a gate electrode 10, an n-type diffusion area 14, a gate spacer 12, and an n+-type diffusion area 16 in the photodiode area PD and the transfer transistor Tx area. The P-type epitaxial layer 4 is formed over a semiconductor substrate 2. The device isolation film 6 is formed in a device isolation area of the semiconductor substrate 2 defined by the photodiode area PD, the active area 1 and the device isolation area.

The gate electrode 10 is formed over the epi-layer 4 with a gate insulating film 8 interposed therebetween. The n-type diffusion area 14 is formed in the epi-layer 4 of the photodiode area PD. The gate spacer 12 is formed over both sidewalls of the gate electrode 10. The n+-type diffusion area 16 is formed by implanting n+-type dopant ions into the epi-layer 4 of the floating diffusion area FD.

In general, the transfer transistor Tx of the 4T type CMOS image sensor has a low threshold voltage. As the threshold voltage of the transfer transistor Tx decreases, a voltage applied to the photodiode PD increases. Accordingly, all the electrons generated at the photodiode PD can be sent to the floating diffusion area FD. However, as shown in FIG. 3, since a difference between the energy levels of the photodiode PD and the transfer transistor Tx is small, leakage current increases when the transfer transistor Tx is turned off.

### SUMMARY

Embodiments relate to a CMOS image sensor capable of preventing leakage current of a transfer transistor and a method of manufacturing thereof. Embodiments relate to a complementary metal-oxide-silicon (CMOS) image sensor including a transfer transistor. The transfer transistor includes an epi-layer formed over a semiconductor substrate defined by a photodiode area, an active area, and a device isolation area. A device isolation film may be formed in the device isolation area. A gate electrode may be formed over the epi-layer for the transfer transistor with a gate insulating film interposed therebetween. A first dopant diffusion area may be formed by implanting first dopant ions into the epi-layer of the photodiode area. A potential well area may be formed in the first dopant diffusion area adjacent to the gate electrode. A second dopant diffusion area may be formed by implanting second dopant ions into the epi-layer of a side-surface floating diffusion area of a gate spacer.

In embodiments, a dose of n-type dopant ions implanted into the potential well area may be lower than that of the second dopant diffusion area and may be higher than that of the first dopant diffusion area. Also, in embodiments, n-type dopant ions may be implanted into the potential well area at a dose of 10¹³ to 10¹⁵ atoms/cm² and an energy of 100 KeV to 150 KeV.

Embodiments relate to a method of manufacturing a CMOS image sensor including a transfer transistor. The method includes forming an epi-layer over a semiconductor substrate defined by a photodiode area, an active area, and a device isolation area. A device isolation film may be formed in the device isolation area. A gate insulating film and a gate metal layer may be sequentially formed over the epi-layer for the transfer transistor. The gate insulating film and the gate metal layer may be patterned and a gate electrode may be formed. First dopant ions may be implanted into the epi-layer of the photodiode area to form a first dopant diffusion area. A potential well area may be formed in the first dopant diffusion area adjacent to the gate electrode. Second dopant ions may be implanted into the epi-layer of a side-surface floating diffusion area of a gate spacer and forming a second dopant diffusion area.

In embodiments, a dose of n-type dopant ions implanted into the potential well area may be lower than that of the dopant ions of the second dopant diffusion area and may be higher than that of the dopant ions of the first dopant diffusion area. Also, in embodiments, n-type dopant ions may be implanted into the potential well area at a dose of 10¹³ to 10¹⁵ atoms/cm² and an energy of 100 KeV to 150 KeV. In embodiments, the forming of the gate electrode may include forming the gate spacer over both sidewalls of the gate electrode. In embodiments, the first dopant may be an n-type dopant and the second dopant may be an n+-type dopant.

### DRAWINGS

FIG. 1 is a plan view showing a related CMOS image sensor.

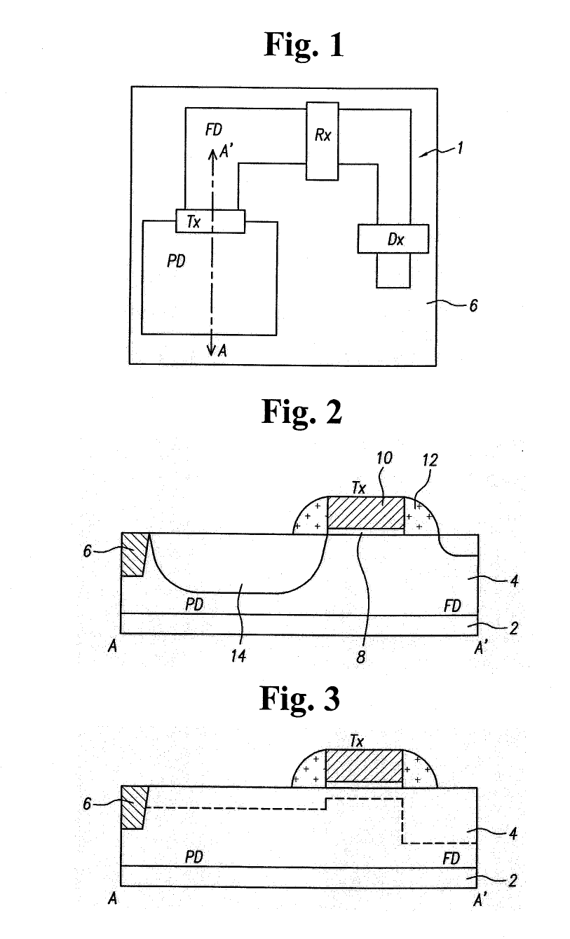

FIG. 2 is a cross-sectional view taken along line A-A′ of the CMOS image sensor shown in FIG. 1.

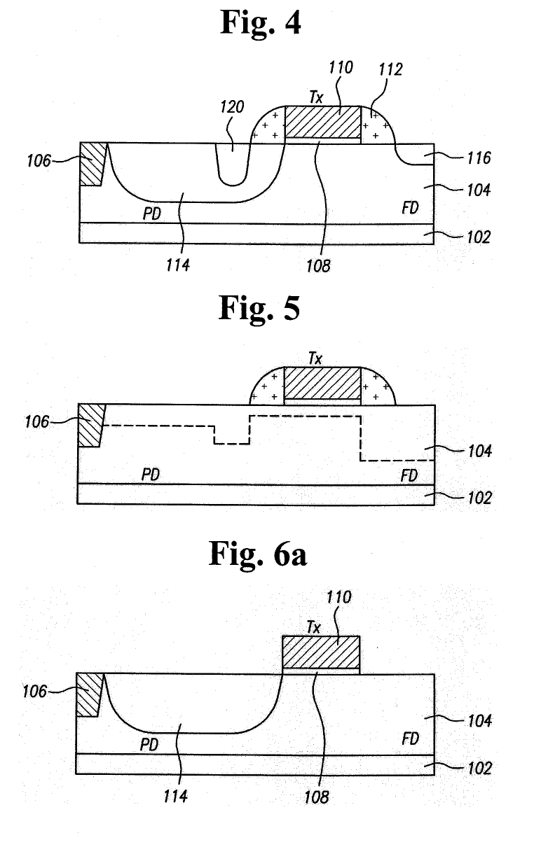

FIG. 3 is a view showing the energy level of the CMOS image sensor shown in FIG. 2.

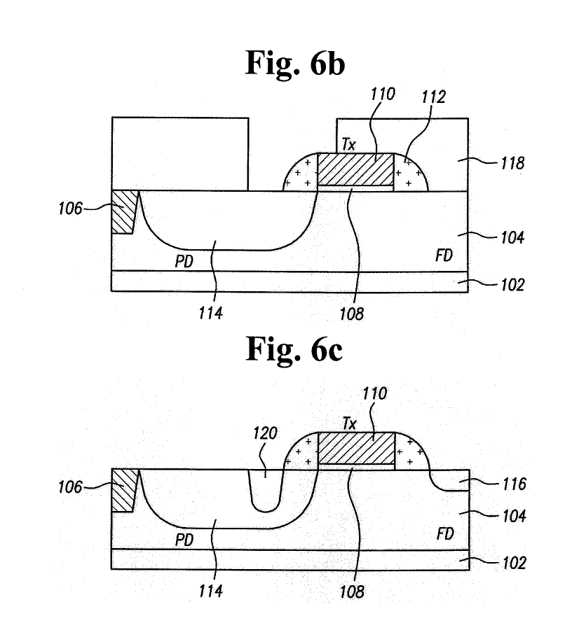

Example FIG. 4 is a cross-sectional view showing a CMOS image sensor according to embodiments.

Example FIG. 5 is a view showing the energy level of the CMOS image sensor shown in example FIG. 4.

Example FIGS. 6A to 6C are views showing a method of manufacturing the CMOS image sensor shown in example FIG. 4.

### DESCRIPTION

Referring to example FIG. 4, the CMOS image sensor according to embodiments includes a transfer transistor. The CMOS image sensor also includes a P-type epi-layer 104, a device isolation film 106, a gate electrode 110, an n-type diffusion area, a gate spacer 112, an n+-type diffusion area 116, and a potential well area 120. The P-type epi-layer 104 is formed over a P+-type semiconductor substrate 102. The device isolation film 106 is formed in a device isolation area of the semiconductor substrate 102 defined by a photodiode area PD, an active area and the device isolation area.

The gate electrode 110 is formed over the epi-layer 104 for the transfer transistor with a gate insulating film 108 interposed therebetween. The n-type diffusion area 114 is formed in the epi-layer 104 of the photodiode area PD. The gate spacer 112 is formed over both sidewalls of the gate electrode 110. The n+-type diffusion area 116 is formed by implanting n+-type dopant ions into the epi-layer 104 of the floating diffusion area FD. The potential well area 120 is formed by implanting n-type dopant ions into the n-type diffusion area 114.

In particular, the potential well area 120 becomes a potential barrier. In more detail, the potential barrier is formed by decreasing the concentration of the n-type diffusion area 114 of the photodiode PD adjacent to the transfer transistor Tx. The amount, that is, the dose, of the n-type dopant ions implanted into the potential well area 120 is set to be lower than that of the dopant ions of the n+-type diffusion area 116 and to be higher than that of the dopant ions of the n-type diffusion area 114. That is, the n-type dopant ions are implanted into the potential well area 120 at a dose of 10¹³ to 10¹⁵ atoms/cm² and an energy of 100 KeV to 150 KeV.

By the above-described ion implantation condition, signal electrons are preferentially collected in the potential well area 120 as shown in example FIG. 5. Accordingly, when the transfer transistor Tx is turned on, electrons flow into the floating diffusion area FD having a lower energy level. In contrast, when the transfer transistor Tx is turned off, the leakage current of the transfer transistor Tx decreases because the energy level of the channel of the transfer transistor Tx is relatively higher than that of the related art.

A method of manufacturing the CMOS image sensor will now be described with reference to FIGS. 6A to 6C. Referring to FIG. 6A, the epi-layer 104, the gate insulating film 108, the gate electrode 110 and the n-type diffusion area 114 are formed over the semiconductor substrate 102. First, the P+-type semiconductor substrate 102 is subjected to an epitaxial process to form a low-concentration P-type epi-layer 104. Thereafter, the gate insulating film 108 and the gate electrode 110 of the transfer transistor Tx are formed over the epi-layer 104.

In more detail, the gate insulating film and a gate metal layer are sequentially formed over the epi-layer 104 by a deposition method. Subsequently, the gate insulating film and the gate metal layer are patterned by a photolithography method using a mask to form the gate insulating film 108 and the gate electrode 110. Thereafter, a photoresist pattern is formed such that the photodiode area PD of the epi-layer 104 is exposed. Next, the n-type dopant ions are implanted into the exposed photodiode area PD to form the n-type diffusion area 114.

As shown in example FIG. 6B, the gate spacer 112 is formed over both sidewalls of the gate electrode 110. In more detail, an insulating film (SiN) is formed over the gate electrode 110 and an etch-back process is performed to form the gate spacer 112 over the sidewalls of the gate electrode 110. Next, a photoresist pattern 118 is formed such that a portion of the n-type diffusion area 114 adjacent to the transfer transistor Tx is exposed.

As shown in example FIG. 6C, the n-type dopant ions are implanted into the exposed n-type diffusion area 114 to form the potential well area 120. The dose of the n-type dopant ions implanted into the potential well area 120 is lower than that of the dopant ions the below-described n+-type diffusion area 116 and is higher than that of the dopant ions of the n-type diffusion area 114. Thereafter, the n+-type diffusion area 116 is formed by implanting the n+-type dopant ions into the epi-layer 104 of the floating diffusion area FD.

This type of reset transistor Rx is also applicable to a 3T type CMOS image sensor. According to embodiments, a potential well area is formed in the n-type diffusion area of a photodiode area PD adjacent to a transfer transistor Tx. Accordingly, in embodiments, leakage current of the transfer transistor Tx is reduced when the transfer transistor Tx is in the off state, because the energy level of the channel of the transfer transistor Tx is relatively higher than that of the related art. According to embodiments, since the electrons generated at the photodiode area PD are collected in the potential well area, there is a reduced probability that electrons are lost while being moved from a place far from the transfer transistor Tx, and thus the sensitivity of the sensor can be improved.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
an epi-layer formed over a semiconductor substrate defined by a photodiode area and an active area;
a gate electrode formed over the epi-layer with a gate insulating film interposed therebetween;
a first dopant diffusion area formed by implanting first dopant ions into the epi-layer of the photodiode area;
a potential well area formed in the first dopant diffusion area adjacent to the gate electrode; and
a second dopant diffusion area formed by implanting second dopant ions into the epi-layer of a side-surface floating diffusion area of a gate spacer.

2. The apparatus of claim 1, wherein a dose of n-type dopant ions implanted into the potential well area is lower than that of the second dopant diffusion area and is higher than that of the first dopant diffusion area.

3. The apparatus of claim 1, wherein n-type dopant ions are implanted into the potential well area at a dose of 10¹³ to 10¹⁵ atoms/cm².

4. The apparatus of claim 1, wherein n-type dopant ions are implanted into the potential well area at an energy of 100 KeV to 150 KeV.

5. The apparatus of claim 1, wherein the first dopant is an n-type dopant.

6. The apparatus of claim 1, wherein the second dopant is an n+-type dopant.

7. The apparatus of claim 1, wherein the gate forms part of a transfer transistor in a complementary metal-oxide-silicon image sensor.

8. The apparatus of claim 7, wherein, when the transfer transistor is in an off state, signal electrons are preferentially collected in the potential well area.

9. The apparatus of claim 7, when the transfer transistor is turned on, signal electrons from the potential well area flow into the second dopant diffusion area having a lower energy level than the energy level of signal electrons outside the potential well area in the first dopant diffusion area.

10. The apparatus of claim 1, wherein the epi-layer formed over a semiconductor substrate is also defined by a device isolation area, and a device isolation film is formed in the device isolation area.

11. A method comprising:
forming an epi-layer over a semiconductor substrate defined by a photodiode area and an active area;
sequentially forming a gate insulating film and a gate metal layer over the epi-layer for the transfer transistor;
patterning the gate insulating film and the gate metal layer to form a gate electrode;
implanting first dopant ions into the epi-layer of the photodiode area to form a first dopant diffusion area;
forming a potential well area in the first dopant diffusion area adjacent to the gate electrode; and
implanting second dopant ions into the epi-layer of a side-surface floating diffusion area of a gate spacer to form a second dopant diffusion area.

12. The method of claim 11, wherein a dose of n-type dopant ions implanted into the potential well area is lower than that of the dopant ions of the second dopant diffusion area and is higher than that of the dopant ions of the first dopant diffusion area.

13. The method of claim 11, wherein n-type dopant ions are implanted into the potential well area at a dose of 10¹³ to 10¹⁵ atoms/cm².

14. The method of claim 11, wherein n-type dopant ions are implanted into the potential well area at an energy of 100 KeV to 150 KeV.

15. The method of claim 11, wherein the forming of the gate electrode comprises forming a gate spacer over sidewalls of the gate electrode.

16. The method of claim 11, wherein the first dopant is an n-type dopant and the second dopant is an n+-type dopant.

17. The method of claim 11, wherein the gate forms part of a transfer transistor in a complementary metal-oxide-silicon image sensor.

18. The method of claim 17, wherein, when the transfer transistor is in an off state, signal electrons are preferentially collected in the potential well area.

19. The method of claim 17, when the transfer transistor is turned on, signal electrons from the potential well area flow into the second dopant diffusion area having a lower energy level than the energy level of signal electrons outside the potential well area in the first dopant diffusion area.

20. The method of claim 11, comprising forming a device isolation film in a device isolation area which additionally defines the semiconductor substrate.
